(19) United States
(12) Patent Application Publication
(10) Pub. No.: US 2008/0204117 A1
(43) Pub. Date: Aug. 28, 2008

(54) Electrical Circuit Arrangement

(75) Inventor: Wolfgang Richter, Germering (DE)

Correspondence Address: KATTEN MUCHIN ROSENMAN LLP, 575 MADISON AVENUE, NEW YORK, NY, 10022-2585, US

(73) Assignee: Ident Technology AG, Wessling (DE)

(21) Appl. No.: 11/816,320

(22) PCT Filed: Feb. 15, 2006
(86) PCT No.: PCT/EP06/01368

§ 371 Date: Aug. 15, 2007

(30) Foreign Application Priority Data
Feb. 15, 2005 (DE) 202005002403.1

(51) Int. Cl. H03K 17/96

(52) U.S. Cl. 327/517

(57) ABSTRACT

The invention relates to an electrical circuit arrangement for generating signal events for initiating or carrying out switching, adjusting or releasing processes. According to the first invention aspect, the inventive electric circuit arrangement comprises an input component for carrying out a selection process for generating an input event and a switching component for generating a switching signal according to the input event evaluation, wherein said input component is constructed in such a way that, in framework of said selection process, the input event is injected into the user actuating the switching component on the base of the interactive effect of electric fields and said switching component is provided with an interface device for detecting the input event injected into the user or acting therein, the input component and the interface device are placed in the operating position in such a way that the signal transmission therebetween is carried out in a signal transmission path integrating the user when it actuates the input component, thereby making it advantageously possible to transmit the user input operation indicative signals to the switching component through said user, wherein said transmission can be carried out only when the user actually initiates an input and thereby can be used in the form of a signal transmitting medium.

The invention relates to an electric circuit arrangement for generating signal events, which can be used as such for initiating, processing or performing switching, positioning or release operations. In this regard the invention is related in particular but not exclusively to the processing of switching or positioning operations while allowing for information, for example concerning authorization of a user, or for physiological or physical data or preferences of the user.

Possible applications of the inventive circuit arrangement can be found in particular in the field of comfort electric systems, in the automotive field, in the field of authorization checking, processing of payment and value-date operations, in computer systems and in the field of medical technology.

Especially in the automotive field, it is known how to design positioning operations for motor-assisted establishment of configurations of the surroundings in a manner desired by the user, such as seat, mirror and steering-wheel configurations, wherein appropriate input switches are actuated by the user. By means of these input switches there are generated switching signals that are conducted via a wiring system to a control device or possibly directly to the respective actuators.

The position in which such input switches are arranged in the motor vehicle can usually be readily accessed ergonomically and easily located intuitively. The wiring of such input switches with the control device or with the associated actuator device has proved in practice to be complicated, especially when such wiring systems have to be installed as retrofit expansions of the equipment.

In other applications also, such as the field of building infrastructures, mounting of the input interfaces and wiring them with the evaluation circuit components frequently cause problems.

The object of the invention is to provide solutions that make it possible to bring about signal transmission or signal acquisition, especially for processing of the said sequences, for example in order to process positioning operations, to activate actuators, to change configurations and/or to verify authorization in a manner that is advantageous, for example with regard to the effort needed for installation and retrofitting.

According to a first aspect of the present invention, this object is inventively achieved by an electric circuit arrangement having an input component for bringing about a selection operation for generation of an input event, and a switching component for generation of a switching signal on the basis of evaluation of the input event, wherein the input component is designed in such a way that, during the selection operation, the input event is coupled on the basis of electric field interaction effects into a user who actuates the switching component, and the switching component includes an interface device for detecting the input event coupled into the user or acting therein, wherein the input component and the interface device are so disposed in service position that the signal transmission between the input component and the interface device takes place with incorporation of the user in a signal-transmission path, when the user actuates the input component.

Thereby it is advantageously possible to transmit the signals indicative of the user's input operation via the user to the switching component, wherein this transmission can take place only if the user has actually requested the input and thus is available as a signal-transmission medium.

It is possible to configure the input component such that it comprises an input panel for processing a range selection. Such an input panel can be underlaid with positioning symbols, so that it is evident, for example by means of a wedge bar, which points have which effect within the input panel. With this concept it is possible in particular to process positioning operations for temperature selection, loudness, bass, pitch and brightness.

In combination with the foregoing measure or as an alternative thereto it is also possible to design the input component such that it comprises a number or character pad. In particular, PIN inputs or other inputs used for authorization verification can be achieved via an input component configured in this way. This configuration is therefore suitable in particular for door-lock systems.

Furthermore, it is also possible to configure the input component such that it comprises a positioning knob or slide device. The input component can be designed such that its outer appearance resembles that of conventional virtual buttons that are typical of the respective intended purpose (such as heating, air-conditioning, seat-configuration, audio, timing and navigation-system virtual buttons). The remaining mechanisms that may also be present can be reduced to position-sensing means, such as potentiometers, angular position sensors and any latching or haptic structures that may be necessary for awareness of any switching. In particular, the input component can be constructed such that the user does not have the feeling that he himself is part of the signal-transmission medium.

It is possible to provide, in the zone of the input component, a display device by which there can be visualized the inputs selected at the time or the effects thereof. In this regard, the input component can also be implemented as a touch-screen structure. The input component can also be made as a touch-pad, trackball or joystick structure. The energy supply of the input device can be obtained from its own energy carrier, batteries, solar cells or even absorber structures, which as such draw the operating energy from the alternating field brought together via the user.

It is possible to implement the input component as a structure that can be used practically wirelessly. To this extent the input component can be designed as a freely installable, substantially flat input surface element. A particularly flat construction for this purpose is obtained by designing the input component as a foil structure. This foil structure can be mounted at a location that is ergonomically readily accessible for a typical application. Mounting can take place on walls or housings, without the need for penetrations or laying of supply lines. Particularly simple installation capability of the input component is achieved for this purpose by equipping it with an adhesive back.

The interface device provided for signal recovery or signal pick-up can be integrated in particular in a door device, a seat device, a steering-wheel device or a door-handle device.

Two concepts, which if necessary can also be implemented in combination with one another, are particularly suitable for achieving signal transmission from the input component to the interface device. In particular, there is possible a concept in which the input component comprises an electrode device and an electronic circuit connected thereto, and in which an electric field is modulated according to a data pattern and coupled into the user via the electrode device in the zone of a selection portion. This field—and thus also the data pattern, can be picked up via the interface device.

Also possible is impedance modulation in the zone of the input component. For example, the resonance frequency of an oscillating circuit provided in the zone of the input component can be modulated, or the electrode device can be grounded in modulated manner via the electronic circuit. These events in the zone of the input component can be detected via the user (as the transmission medium) in the zone of the interface device, so that a corresponding information or signal flow becomes possible.

The interface device mentioned in the foregoing is an electrode device. This electrode device is preferably designed as a flat electrode that is completely insulated externally or else as a wire, which is preferably insulated. Essentially no currents beyond the current flow necessary for establishing the field or for picking up the field at the interface device flow through these interface devices.

On the basis of the concept underlying the invention, it will also be possible to consider the criterion of “user presence” as a logic parameter during processing of the switching sequences.

In vehicles, especially motor vehicles, for example, persons sit on seats and operate switches that generate an effect in their zone of influence. Thus lights can be turned on and off, or ventilation and temperature can be regulated. Especially in vehicles, it is possible to provide common switches instead of separate switches for driver and passenger, for the purpose of turning the desired functions on or off in the surrounding area. On the basis of the inventive solution concept, it is possible to guarantee that impermissible or erroneous operation of knobs and input structures by a passenger will have no function or only certain functions that are still permissible. Of special importance are control elements that actually only the driver is permitted to operate for driving operation, although they are accessible to the passenger and could be actuated inadvertently. Erroneous actuation of such switches can be prevented on the basis of the inventive circuit.

In particular, it is possible by means of the inventive circuit to identify the person actuating a switch or a positioning device or to identify his seat position and to make only certain functions accessible for that person or seat position. For this purpose a dialog is preferably conducted via the skin of an operating person.

Foils for heating the seat or detecting whether a seat is occupied are often located in a vehicle seat. By incorporating the inventive circuit, this foil can be used to generate an electrical alternating field with respect to a person sitting on it. This alternating field forms a kind of synthetic aura with the person, because the charges become distributed over the surface of the skin.

If a person sitting on such a foil touches a switch, the impressed alternating fields can be drained toward this. The invention takes advantage of the circumstance that it is possible to modulate these alternating fields with identifiable data and to transmit to a selected switch and back via the skin of a person acting from this seat. Since both the seat foil and the switch are connected to the vehicle ground, an alternating current circuit is formed in principle. The embodiment of the invention is obviously particularly advantageous, since only very few components must be used.

Further details and features of the invention will become evident from the following description in conjunction with the drawing, wherein:

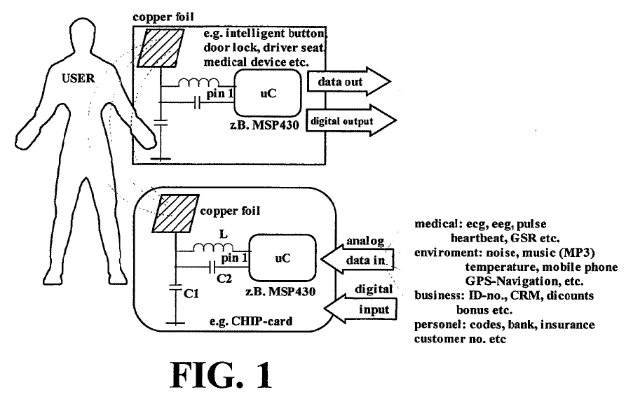

FIG. 1 shows a simplified diagram of the inventive circuit comprising an input component and a switching component;

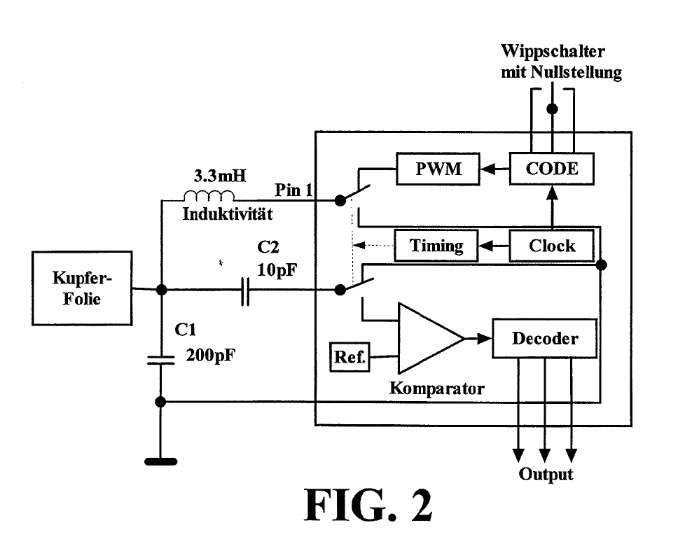

FIG. 2 shows a simplified diagram for explanation of further possible details of the switching component;

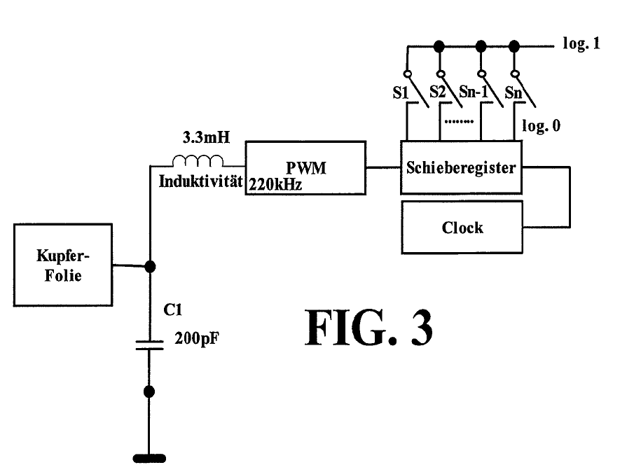

FIG. 3 shows a simplified diagram for explanation of the structure of an input component provided therein with a shift register for signal generation and a pulse-width modulator (PWM) on the output side;

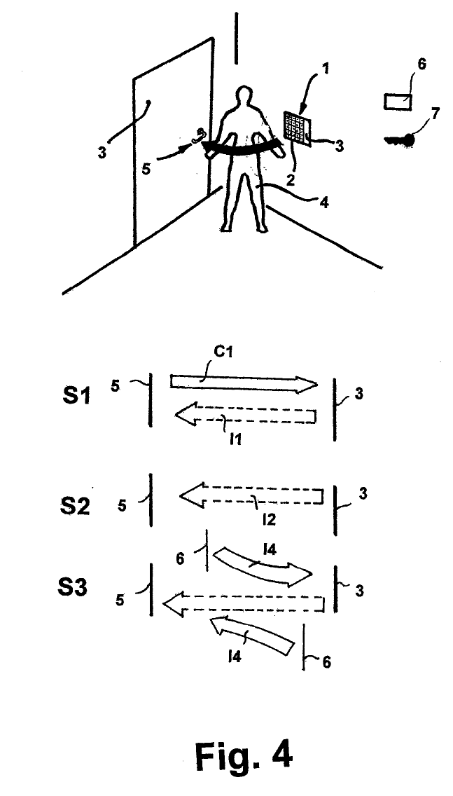

FIG. 4 shows a sketch for explanation of a form of application of the inventive circuit in a door-lock system with authorization-dependent door interlock;

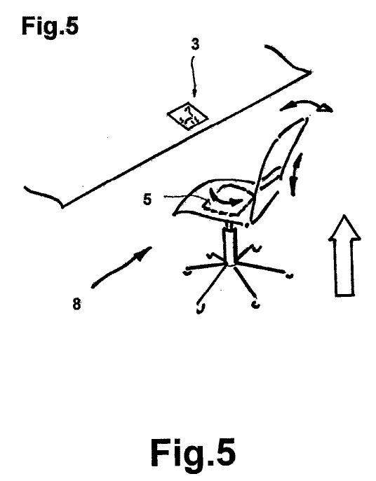

FIG. 5 shows a sketch for explanation of a form of application of the inventive circuit in a seat with integrated comfort mechanisms;

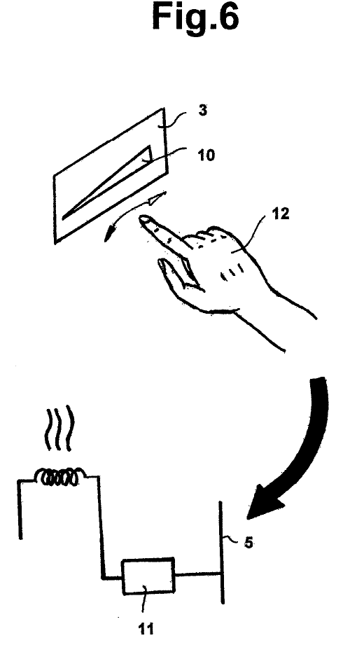

FIG. 6 shows a sketch for explanation of a form of application of the inventive circuit as a positioning device for a seat heater.

FIG. 1 shows a circuit arrangement in which a copper foil is coupled to the junction point between coil and capacitor of a series oscillating circuit. This electrode is mounted in insulated manner, for example in a driver's seat. It forms one side of a capacitor. A person sitting on this seat forms (with his buttocks) the opposite side. Since human skin is conductive, the modulated alternating field is transmitted thereon. A switch contains a receiving foil and a parallel oscillating circuit, whose output is connected via a capacitor to a comparator. If the person sitting on the first foil touches this switch, a capacitor is also formed between the finger and the foil in the switch, and so the modulated alternating field appears at the comparator. This is adjusted such that its threshold value converts the modulated alternating field into a square-wave signal. By means of a detector, the data from the resonance frequency can now be recovered and relayed to the control unit of the motor vehicle.

Via a series oscillating circuit, for example, an oscillator generates an alternating field with high voltage level (>50 volts). Data can be impressed on the resonance frequency via a modulator.

FIG. 2 shows a microcontroller module. The series switching circuit is connected to one of its pins (for example, pin 1). A capacitor C2 leads from this to a further pin, which can be connected internally to a comparator. During sending operation, this pin is connected internally to ground, since otherwise high voltage would reach the controller and possibly destroy it. This microcontroller is able to turn pin 1 on and off in such a way that the series oscillating circuit reaches resonance and a higher voltage (alternating field) becomes available at the copper foil. This is modulated to the effect that an identification character (such as “F” for driver, “B” for passenger or “R” for back seat, etc.) having a particular output speed (bit rate) influences the generation of the alternating field. In the simplest case, the alternating field will be generated with a logical 1, whereas the bit length remains turned off (ASK) with a logical 0. In exactly the same way it is possible for a 1 to generate a frequency slightly above and for a logical 0 to generate a frequency slightly below the resonance frequency (FSK). In principle, all known modulation methods that can be digitally output are usable. The circuit in the switching element is designed in exactly the same way as that in the seat. Here, however, pin 1 is first connected internally to ground, so that the series oscillating circuit is converted to a parallel oscillating circuit, at whose middle tapping point capacitor C2 is connected to the internal comparator. This capacitor is smaller than that of the resonance circuit, so that the deviation from the maximum of the resonance frequency will not become too large. The alternating-current signal injected via the finger of the operating person causes the parallel oscillating circuit to develop a high input impedance at the resonance condition. Thus a high voltage level at the capacitor drops at the internal comparator. After the first circuit has sent out its identification data, it also connects the oscillating circuit internally to ground at pin 1, and is therefore capable of receiving. Now the switch in turn can modulate the series oscillating circuit (and connect small capacitor C2 to ground), thereby reversing the data direction. This is practical, as illustrated by the first example of use.

### EXAMPLE OF USE

Seat-heating foils, each coupled with an inventive switching component, are disposed in the driver's and passenger's seats. The circuit in the driver's seat continuously sends an “F” and is briefly capable of receiving after each time it sends out an “F”, whereas the circuit in the passenger's seat sends out a “B”. A switch that can be turned both to the left and to the right (rocker) and is supposed to be used for adjusting the temperature of the seat heater is disposed on the dashboard. The seat heaters are connected via regulating transistors to the circuit in the seat and can be influenced by these. If the driver, for example, actuates the switch in order to choose a higher temperature, this switch sends a plus character “+”, for example, via the driver's skin into his seat. The circuit there recognizes the plus and causes the heater regulator to raise the temperature. If the passenger subsequently actuates the same switch, for example to lower his seat temperature, he actuates the switch in the other direction. Thereupon this sends a minus “−” via the passenger's skin to his seat and his circuit, etc. Without the use of an external control unit, it is therefore possible in simple manner to adjust different temperatures for different seats, even though the same switch is always actuated. This means less complexity with greater comfort (expediently, switches to be operated simultaneously by the driver and passenger can be mounted in the middle of the dashboard or on the central console). Furthermore, knobs for lights on the respective side or for seat adjustment can be provided in addition to that for the heater setting.

In aircraft, these switches can locally select the audio system, the ventilation or the stewardess call. The stewardess then sees on a display who has pressed the button, and does not have to look awkwardly for the light. Instead of a microcontroller, there can also be used a shift register with pulse-width modulator (PWM) on the output side for signal generation (FIG. 3).

### Further Embodiments

The circuit can also be installed in keys or key chains, in order to communicate with a counterpart installed in a lock when the key is inserted in the lock. Likewise control elements and vehicle parts (arm rests, levers, pedals, belts, lights in side pockets) can be activated with the inventive circuit. Furthermore, there can be transmitted variable data, for example of sensors, timers, etc., and of audio nature (for example to headphones or to a hearing aid). The latter capability could transmit the instructions of a navigation system in the vehicle to an earphone of hearing-impaired drivers via the steering wheel, without interfering background noise.

The inventive circuit is suitable in particular for creating an audio virtual button that can be positioned without effort and mounted easily. The further components of the audio or even video system can be disposed in theft-proof manner in relatively inaccessible zones, such as the interior space of doors or the side zones of the trunk. The inventive circuit also makes it possible to design the switching devices that may be provided in a zone of the passenger compartment that is potentially exposed to passenger impact in such a way that they are less likely to cause injury. By means of the inventive circuit it is also possible to dispose display systems that are safe in the event of a crash and to provide seats with their own adjustment input units and additional input interfaces for control or positioning instructions.

FIG. 4 shows an example of an application for the inventive circuit in a door system. An inventive input component 1 is mounted at hand height in the vicinity of a door 3. This input component 1 comprises a number pad 2 and a display device 3. If user 4 touches input component 1 in the zone of number pad 2, an event indicative of the selection of a number in the number pad is coupled into the user. This event can be picked up via interface device 5 provided on the door side, in the door handle, door stop or lock plate, and in this way made accessible to further signal-processing analysis.

It is possible to configure the system in such a way that signal transmission (large arrow) is already possible when user 4 is sufficiently close to door 3. It is also possible to prompt for contact with the interface device. It is possible to conduct signal transmission simultaneously during operation of the input component. It is also possible to design the input component in such a way that a particular sequence of numbers or characters must be input first to the input component, after which this sequence is communicated only if a send key is selected, a certain number of selections has been made, a certain time has elapsed or some other specified send criterion has been satisfied. The existence of touch contact with the door handle or a particular intensity-increase profile during approach to the handle is also particularly suitable as the send criterion.

It is possible to include circuit-engineering precautions by which the data transmitted to the door or to the interface device provided there are encoded.

Furthermore, it is possible to make access acquisition, or in other words release of the door, contingent upon whether user 4 satisfies further criteria provided for authorization verification. For example, it is also possible to require that an ID card 6 and/or a mechanical key 7 also be carried along. Via the ID card, signals to be read out on the side of input component 3 and/or by the system components in the door can be coupled into the user, preferably again on the basis of electric field interaction effects. As an example, a particular required PIN number can be determined from these signals, and so different PIN numbers are needed for access acquisition by different users. The information provided via ID card 6 or input device 3 can also be taken into consideration for time recording or documentation of occupancy.

As indicated in sketch S1, a signal C1 in the form of a modulated field can be coupled into user 4 via interface device 5. Corresponding to the actuation of input component 3, impedance modulation can be imposed thereby, so that feedback of information I1 to the zone of interface device 5 takes place on the basis of this impedance modulation.

As indicated in sketch S2, it is also possible to design input component 3 in such a way that it communicates information I2 “unidirectionally” to interface device 5 with corresponding signal coupling into user 4.

According to sketch S3, it is possible, by means of circuits worn or carried by the user (ID card 6), to hold additional information I3, I4 in readiness for use by the door system or input circuit.

The measures outlined in the foregoing with reference to a door system can also be used in similar form for processing of switching and control operations for other purposes, especially in automotive applications, and thus are also subject matter of the present invention above and beyond the specifically described application.

FIG. 5 shows an application for the use of the inventive circuit in a seat device 8 equipped with a positioning drive. The seat device comprises an electrode device 5 integrated into the seat cushion. Activation of the seat device with respect to seat height, back inclination, back curvature and possibly adjustment options takes place via an input device 3, which can be placed as a flat foil unit in a location chosen by the user side, and in particular mounted on a table surface. By touching input device 3 in the zones identified by symbols, signal feedback to interface device 5 can be achieved, in turn leading to a corresponding adjustment of the seat. This concept is also suitable in particular for chairs in vehicles and chairs in nursing institutes, and especially also for hospital beds. It is possible to provide, in the vicinity of typical spaces for chairs or beds, virtual buttons in the form of that input component 3 by which a change of configuration of the chair or bed or other configurable device is achieved. Here also it is possible to make the permissibility of the positioning operation contingent on the presence of further signals, especially of an ID card (which also has the capability of coupling in signals) being worn or carried by a nursing staff member or patient.

FIG. 6 schematically shows an input component 3 with a wedge bar 10 displayed thereon. Depending on the position at which wedge bar 10 is touched by the hand 12 of a user, signals indicative of this touch position are coupled into the user. These signals can be picked up via interface device 5, which is disposed in the vicinity of the user, and processed by a switching component 11 in order to be used for heating control. Signal transmission from input component 3 to interface device 5 takes place wirelessly via the user.

Switching component 11 can be integrated in the subassembly to be controlled, such as a seat, door lock, heating valve, power controller, etc.

1. An electric circuit arrangement compromising:
an input component for bringing about a selection operation for generation of an input event, and
a switching component for generation of a switching signal by signal-processing evaluation of the input event,
wherein the input component is designed in such a way that, during the selection operation, the input event is coupled on the basis of electric field interaction effects into a user who actuates the input component, and the switching component includes an interface device for detecting the input event coupled into the user,
wherein the input component and the interface device are so disposed in service position that the signal transmission between the input component and the interface device takes place with incorporation of the user in a signal-transmission path, when the user actuates the input component.

2. A circuit arrangement according to claim 1, wherein the input component compromises an input panel for processing a range selection.

3. A circuit arrangement according to claim 1, characterized in that the input component compromises one of a number and character pad.

4. A circuit arrangement according to claim 1, wherein the input component comprises a positioning knob device.

5. A circuit arrangement according to claim 1, wherein the input component comprises a display device.

6. A circuit arrangement according to claim 1, wherein the input component is designed as a freely installable, substantially flat input surface element.

7. A circuit arrangement according to claim 1, wherein the input component is designed as a foil structure.

8. A circuit arrangement according to claim 1, wherein the input component is equipped with an adhesive back.

9. A circuit arrangement according to claim 1, wherein the interface device is integrated in one of a seat device, a steering-wheel device, and a door handle device.

10. A circuit arrangement according to claim 1, wherein the input component compromises an electrode device and an electronic circuit connected thereto, and in that an electric field is modulated according to a date pattern and coupled into the user via the electrode device in the zone of a selection portion.

11. A circuit arrangement according to claim 10, wherein the electrode device is grounded in modulated manner via the electronic circuit.
